(19) United States
(12) Patent Application Publication
(10) Pub. No.: US 2026/0179205 A1
(43) Pub. Date: Jun. 25, 2026

(54) METHOD AND SYSTEM FOR OVERLAY METROLOGY MEASUREMENT

(71) Applicant: CANON KABUSHIKI KAISHA, Tokyo (JP)

(72) Inventors: Nilabh K. Roy, Cedar Park, TX (US); Byung-Jin Choi, Austin, TX (US)

(21) Appl. No.: 18/990,096

(22) Filed: Dec. 20, 2024

(51) Int. Cl. G06T 7/00; H01L 21/66; H01L 21/687

(52) U.S. Cl. CPC G06T 7/0004; H10P 72/7604; H10P 74/23; G06T 2207/30148

(57) ABSTRACT

A method of measuring an overlay error of at least one die bonded to a substrate includes capturing a first image of at least one first metrology mark having a first pattern on an object, capturing a second image of at least one second metrology mark having a second pattern on a surface of the at least one die, superposing the second image with the first image to form a simulated interference pattern, determining a metrology mark error based on the simulated interference pattern, and obtaining the overlay error based on alignment marks placement errors of a source substrate, offsets that occurred during the capturing of the first image and the second image, and the determined metrology mark error.

### BACKGROUND

### Field of Art

The present disclosure relates to semiconductor processing, and more specifically relates to systems and methods for measuring overlay errors in bonding semiconductor materials.

### Description of the Related Art

Currently, in a flip chip to wafer bonding process, the overlay metrology is not well established to measure overlay errors between the bonded dies and substrate with less than 10 nm resolution.

In order to properly measure overly errors, dedicated Infrared (IR) metrology marks and zones are often allocated on the dies for placing the alignment marks. However, such dedicated zones are devoid of any circuitry metal features because these circuitries can degrade the IR imaging quality and resolution. Thus, the usable areas on the dies will be reduced due to these dedicated zones. Also, as the metrology is performed by IR imaging device through the dies, metrology resolution may be degraded due to longer IR wavelengths and thus very hard to achieve less than 10 nm overlay measurement resolution.

It is desirable to minimize the space required for the alignment markings. Further, it is desirable to measure overlay errors without using IR imaging devices.

### SUMMARY

According to an aspect of the present disclosure, a method of measuring an overlay error of at least one die bonded to a substrate includes capturing a first image, by an imaging device, of at least one first metrology mark having a first pattern on an object with a first positional information, capturing a second image, by the imaging device, of at least one second metrology mark having a second pattern on a surface of the at least one die with a second positional information, superposing the second image with the first image to form a simulated interference pattern, determining a metrology mark error based on the simulated interference pattern in X, Y and 0 directions, and obtaining the overlay error based on alignment marks placement errors of a source substrate, offsets that occurred during the capturing of the first image and the second image, and the determined metrology mark error.

Further features of the present disclosure will become apparent from the following description of exemplary embodiments with reference to the attached drawings.

### BRIEF DESCRIPTION OF THE DRAWINGS

FIG. 1 is a top-down view of a destination substrate that includes a plurality of dies bonded thereon according to an embodiment of the present disclosure.

FIG. 2 is a cross-section view of the metrology apparatus according to an embodiment of the present disclosure.

FIG. 3 illustrates an example of using substrate metrology mark and die metrology mark to form an interference pattern.

FIGS. 4A and 4B illustrate exemplary operations of the metrology apparatus for capturing substrate metrology marks and die metrology marks.

FIGS. 5A and 5B illustrate examples of forming simulated interference patterns.

FIG. 6 is a flowchart illustrating a process for determining overly metrology errors.

FIGS. 7A and 7B illustrate various embodiments for capturing a die metrology mark.

FIGS. 8A and 8B illustrate an active side and the opposite non-active side of the source substrate prior to a singulation process.

FIG. 9 illustrates an exemplary configuration for measuring alignment marks of the source substrate.

FIGS. 10A and 10B illustrate an error caused by a z-motion movement of the optical device.

FIG. 11 illustrates an example of measurement results from multiple metrology marks.

### DESCRIPTION OF THE EMBODIMENTS

Exemplary embodiments of the present disclosure will be described in detail below with reference to the attached drawings. The following exemplary embodiments are not intended to limit the claimed disclosure, and not all combinations of features described in the exemplary embodiments are necessarily deemed to be essential. The same components are denoted by the same reference numerals, and descriptions thereof are omitted.

In the specification and the accompanying drawings, directions will be typically indicated on an XYZ coordinate system in which a surface parallel to a horizontal surface is defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the OX-axis, the OY-axis, and the OZ-axis means control or driving concerning a rotation about an axis parallel to the X-axis, a rotation about an axis parallel to the Y-axis, and a rotation about an axis parallel to the Z-axis, respectively.

In embodiments to be described later, an example in which a substrate (or wafer) on which semiconductor devices are formed and a die (or a chip) obtained by dividing into pieces a substrate on which semiconductor devices are formed will be explained. However, various changes and modifications can be made within the scope of the present disclosure. In the embodiments to be described later, various temporary or permanent bonding methods can be applied as a bonding method. Examples of the bonding method are bonding using an adhesive, temporary bonding using a temporal adhesive, bonding by hybrid bonding, atomic diffusion bonding, vacuum bonding, and bump bonding.

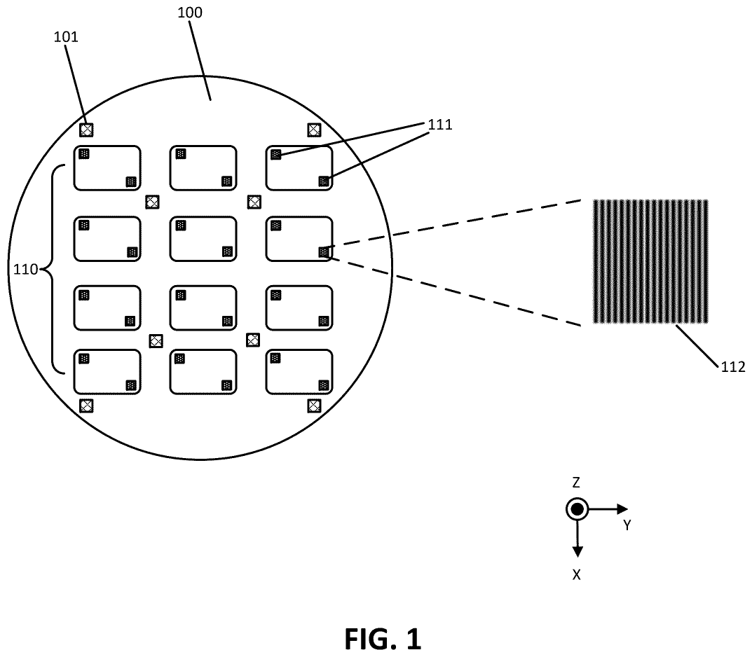

FIG. 1 is a top-down view of a destination substrate 100 that includes a plurality of dies with metrology marks in accordance with an embodiment of the present disclosure. The destination substrate 100 may be composed of semiconductor material. The destination substrate 100 includes one or more substrate metrology marks 101 and a plurality of dies 110 bonded thereon. The individual dies 110 may be a part of an integrated circuit product that includes electrical elements. The die 110 may include one or more transistors, supporting circuitry to route electrical signals to other integrated circuit components.

In this embodiment, each of the dies 110 includes one or more die metrology marks 111 which are formed on the non-active or back surfaces of the dies on a surface opposite a bonding surface of the die. The die metrology mark 110 may be formed of grating lines as illustrated in the close-up view 112. In the illustrative embodiment, the pitch between grating lines of the die metrology mark 110 may be 0.5 μm to 1 μm. In another embodiment, the pitch of the metrology mark may be 0.5 μm to 20 μm. When moiré amplification is used, the substrate metrology marks 101 will have a different pitch than the die metrology marks 110. For example, if the difference in the pitches is on the order of 2-3% than a relatively large moiré amplification can be achieved. The width of each grating line may be any suitable amount, such as 10-90% of the pitch. The overall size of the substrate metrology mark and the die metrology mark may be the same or different depending on actual application. The shape of the substrate metrology mark and the die metrology mark may be square, rectangular, or any other shapes. However, the direction and orientation of the gratings are not limited to this example.

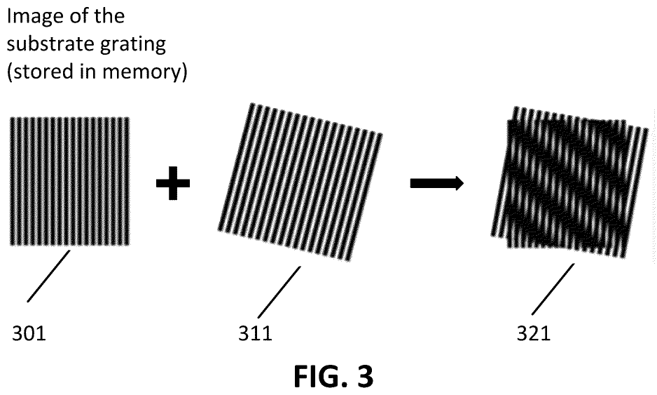

The grating lines of the metrology marks may be formed by any suitable material including but not limited to silicon, silicon oxide, metal, dielectric, and/or any other suitable material that reflects or absorbs light. An example of the gratings of substrate metrology marks 101 and die metrology marks 111 is moiré gratings. The gratings or patterns of the substrate metrology marks 101 and die metrology marks 111 shall be complementary to each other such that when the patterns are overlayed on top of one other, a moiré interference pattern may be observed and overlay metrology error can be determined. The process of determining metrology mark errors based on these metrology marks will be explained in further details below in connection with FIG. 3.

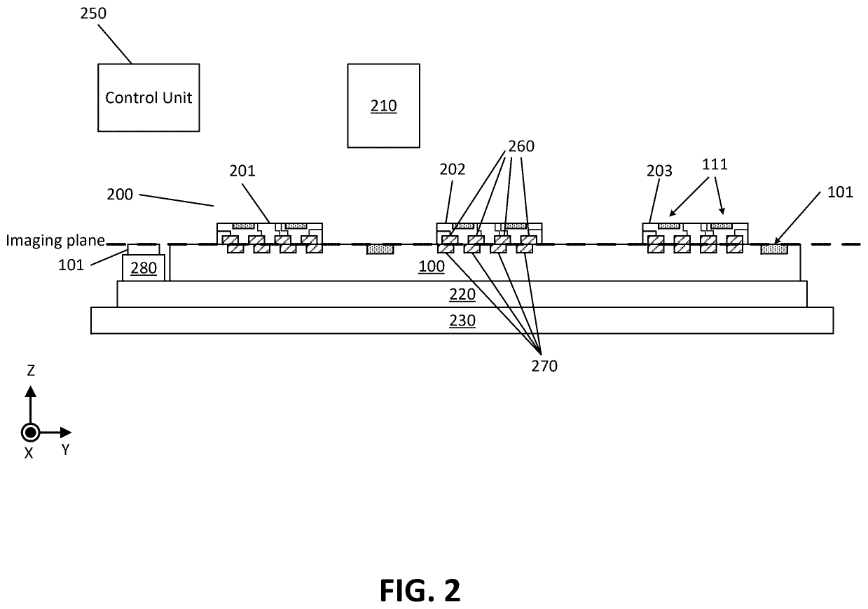

FIG. 2 illustrates an exemplary configuration of a metrology apparatus 200. The metrology apparatus 200 includes an imaging unit 210, substrate stage 220, base plate 230, and control unit 250. For illustrative purposes, destination substrate 100 is bonded with dies 201, 202, and 203. Each of the dies includes a plurality of die bonding pads 260 which shall be aligned with substrate bonding pads 270. Die 203 illustrates an example of a die perfectly aligned with the substrate where each of the die bonding pads 260 is aligned with the corresponding substrate bonding pads 270. Die 202 illustrates an example of a die mis-aligned with the destination substrate 100 where each of the die bonding pads 260 is shifted to the right with respect to substrate bonding pads 270. Die 201 illustrates an example of a die mis-aligned with the substrate where each of the die bonding pads 260 is shifted to the left with respect to substrate bonding pads 270. Some mis-alignment of the bonding pads is acceptable and expected. The amount of mis-alignment can have an impact on the electrical characteristics of the bond between the substrate bonding pads 270 and the die bonding pads 260. The amount of mis-alignment is represented by the measured overlay errors. The measured overlay error can be a good indicator of the quality of the electrical connections between the die and the substrate after bonding. The substrate stage 220 includes a substrate chuck (not shown) which releasably secures the destination substrate 100 to the substrate stage. The substrate stage 220 is connected to a base plate 230 that uses its internal driving mechanism which includes various motors and actuators to position the destination substrate 100 at a desired position. It shall be understood while one of each unit is described in this example, more than one of each element may be included in the metrology apparatus 200. For instance, more than one imaging unit and more than one control unit may be included in the metrology apparatus 200. In an alternative embodiment, the substrate metrology marks 101 are not located on the substrate, rather, the substrate metrology marks 101 are located on a frame 280 connected to the substrate stage 220. The frame 280 can be a part of the substrate chuck or adjacent to the substrate chuck. When the substrate stage 220 moves the substrate chuck (which is holding the substrate), the frame 280 with the substrate metrology marks 101 move in concert with the substrate chuck.

The imaging unit 210 may be a microscope that includes an imaging sensor such as a complementary metal oxide semiconductor (CMOS) or a charge-coupled device (CCD) with numerical aperture (NA) of 0.02 to 0.3, displacement magnification (amplification due to moiré interference pattern of gratings) of 10-200×, optics resolution with 1-20× optical magnification of 1-100 nm. The imaging unit 210 can includes a driving mechanism (not shown) which enables the imaging unit 210 to move in the X, Y, Z, and θ directions. Such driving mechanism may be made of various motors and actuators. As a result, the imaging unit 210 is capable of capturing images at any locations of the destination substrate 100. The captured images can then be transferred to a memory of the control unit 250.

The control unit 250 includes at least one Central Processing Unit (CPU) and at least one memory storing instructions to be performed by the CPU, and controls the entirety (respective parts) of the metrology apparatus 200. Furthermore, the control unit 250 controls the metrology measurement, the alignment processing, and other processing associated therewith. Note that the number of the control unit is not limited to one, and more than one control unit may be used to control the respective parts.

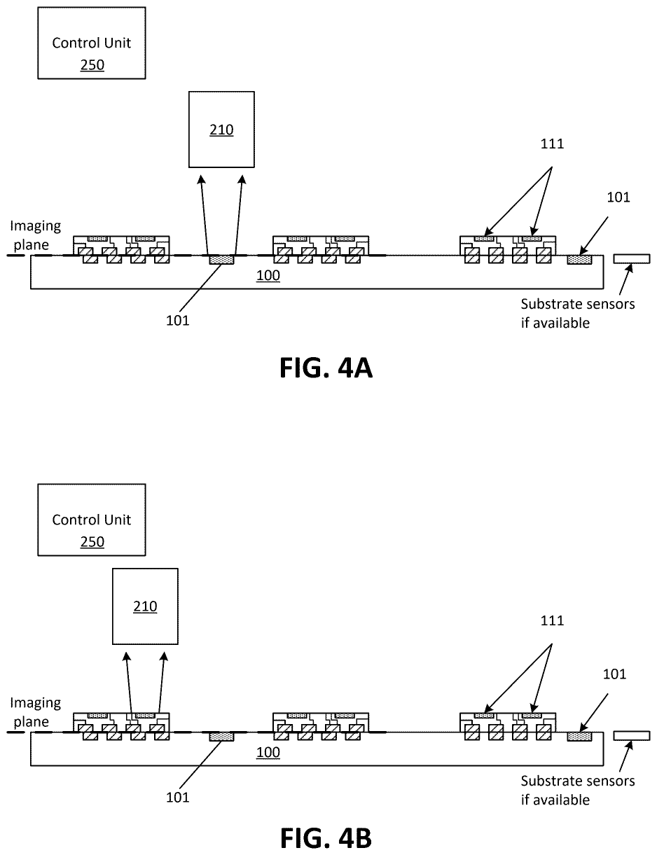

In this illustrative embodiment, the control unit 250 causes the imaging unit 210 to capture the image of each of the substrate metrology marks 101 and storing the captured images in its memory. FIGS. 4A and 4B illustrate exemplary operations of the metrology apparatus for capturing substrate metrology marks and die metrology marks corresponding to the metrology apparatus of FIG. 2 described above. As shown in FIG. 4A, prior to capturing the images, imaging unit 210 is moved to the nominal position above of a substrate metrology mark 101 by a driving mechanism with precision positioning capability using sensing such as interferometers. This nominal position information of the substrate metrology mark may be available from design files (e.g., gds files) for the driving mechanism to drive to. The control unit 250 then causes the imaging unit 210 to capture the image of the substrate metrology marks 101 and store the image of the substrate metrology mark 101. The image may be cropped, filtered, denoised for further processing. The substrate metrology mark 101 is recorded in a global or tool coordinate system. The positional and orientational information of the substrate metrology mark 101 in the X, Y, and θ coordinate is subsequently stored in the memory. Similar process will be performed to capture each of the substrate metrology marks 101. In another embodiment, instead of moving the imaging unit 210, the control unit 210 causes the base plate 230 to move such that the imaging unit 210 is positioned above of the substrate metrology mark 101 (corresponding to FIG. 4A).

Subsequently, imaging unit 210 is moved to a position above of a die metrology mark 111 by a driving mechanism as illustrated in FIG. 4B. Accordingly, images of the die metrology mark 111 and can be taken without obstruction. As shown in FIG. 4B, the control unit 250 then causes the imaging unit 210 to capture the image of the die metrology marks 111 and storing the image of the substrate metrology mark 101. The die metrology mark 111 is recorded in the same global/tool coordinate system as the substrate metrology mark 101 with positional and orientational information. Similar process will be performed to capture each of the substrate metrology marks 111. In another embodiment, instead of moving the imaging unit 210, the control unit 250 causes the substrate stage 220 to move such that the imaging unit 210 is positioned above of the die metrology mark 111 (corresponding to FIG. 4B).

Upon being recorded in the global coordinate system, the control unit 250 performs superposition of the image of the substrate metrology mark 101 and die metrology mark 111 by digitally superposing the marks to form a simulated overlay interference pattern. In the context of the present embodiment, superposing the marks means a point-by-point multiplication of the image intensities of the two images in spatial domain. For example, the image of the substrate metrology mark 101 is stored in memory as a substrate array of pixels, and the image of the die metrology mark 111 is stored in memory as a die array of pixels. In the processing of superposing the marks, each pixel in the substrate array of pixels is multiplied by the corresponding die array of pixels to form a simulated array of pixels that represents a simulated overlay interference pattern. Storing these images in the global coordinate system can include shifting the relative positions of the image. This shifting can include determining an amount of shifting based on the relative position of the stage, the relative position of the substrate metrology mark to the substrate bonding pads, and/or the relative position of the die metrology mark to the die bonding pads.

FIG. 3 illustrates the captured images of substrate metrology mark and die metrology mark. In this example, substrate metrology mark 301 and die metrology mark 311 are both images of the moiré gratings stored in the memory. The simulated overlay interference pattern 321 is a moiré interference pattern that is formed by superposing a substrate metrology mark 301 and die metrology mark 311. If the pitch of the first overlay metrology mark is p₁ and the pitch of the second overlay metrology mark is p₂, then the pitch of the resultant moiré interference fringe has a period P_{F} given by equation (1) below:

$${P}_{F} = \frac{( {p}_{1} {p}_{2} )}{( {p}_{1} - {p}_{2} )} \qquad ( 1 )$$

As an example, p₁=3.6 μm, p₂=3.7 μm would produce a moiré interference pattern with period, P_{F}=133.2 μm. The displacement magnification, D_{mag} for the metrology is estimated by the following equation:

$$\begin{matrix}{D}_{mag} = \frac{( {O}_{mag} * {P}_{F} * k )}{{P}_{av}} \\ {P}_{av} = \frac{2 {p}_{1} {p}_{2}}{( {p}_{1} + {p}_{2} )}\end{matrix} \qquad ( 2 )$$

where, O_{mag}=optical magnification (1×, 5×, 10×, 20×, 50×, 100×) of the imaging unit 210;
P_{F}=Fringe period/pitch;
Pₐᵥ=Average grating period/pitch;
k=moiré pattern factor=2 if the two complementary grating patterns are designed to produce counter propagating fringes else k=1;

The displacement magnification is the amplification that is observed by the imaging unit 210 by relative displacement of the die metrology mark 111 relative to the substrate metrology mark 101. For example, if the substrate metrology mark 101 has a pitch p₁=3.6 μm, the die metrology mark has a pitch p₂=3.7 μm that produce counter propagating fringes, the fringe pitch (P_{F})=133.2 μm and assuming the imaging unit 210 has an optical magnification of 5X, the displacement magnification D_{mag} would be 365. This means that a 10 nm motion of one of the metrology marks relative to the other would produce a 3.65 μm motion of the moiré interference fringes on the CCD/CMOS sensor of the imaging unit 210. Additional improvement in displacement detection sensitivity can be obtained by phase analysis of the counter propagating moiré fringes, high dynamic range with large number of pixels sensors. In another embodiment, Fourier analysis may be performed on the simulated interference pattern. The phase information from the Fourier analysis can then be used to obtain using these algorithmic approaches, the relative alignment error (X, Y, θ) for each die metrology mark 111 is obtained relative to the substrate metrology mark 101 offset. Based on the above equation, the metrology mark errors between a substrate metrology mark 301 and die metrology mark 311 can be determined. The process shall be repeated for each of the metrology marks.

By digitally simulating the interference pattern using the stored metrology mark of the substrate and backside metrology mark of the die, the metrology marks do not need to be physically overlayed above one other. Hence, the metrology marks do not need to be formed in any dedicated regions on the substrate or the die. Further, the images of the substrate metrology mark and the die metrology marks can be obtained by imaging devices with low NA and low magnification. In another embodiment, the images of the substrate metrology mark and the die metrology marks can be obtained by imaging devices with high NA. Also, by not requiring the metrology marks to be physically overlayed above each other, no imaging through the die is necessary to obtain the interference pattern. The interference pattern is not limited to moiré patterns. For example, the metrology marks 301 and 311 may be a box-in-box, bar in bar, cross-in-cross, checkerboard, bullseye, vernier scale marks, or cross-in-box patterns. Optics design and image analysis algorithms used for extracting alignment error information would be different to achieve as fine sensitivity as the moiré interference-based metrology.

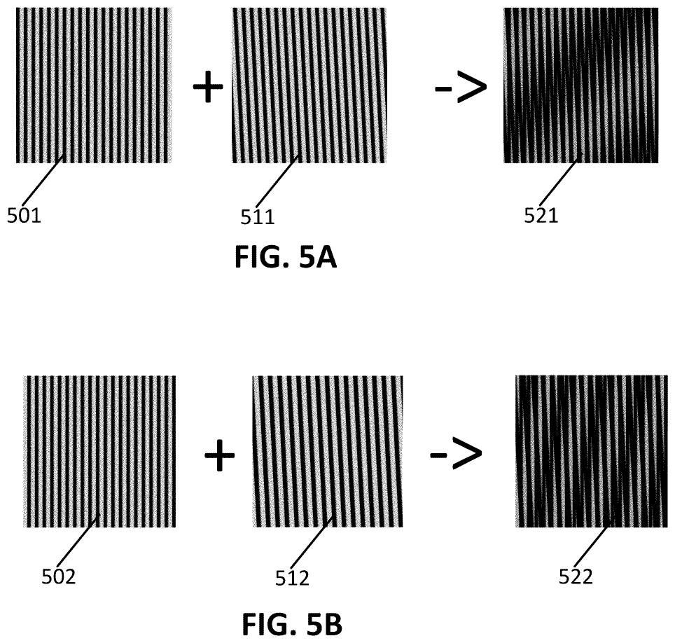

FIGS. 5A and 5B illustrate examples of the metrology marks images obtained using different parameters. Stored image of the substrate metrology mark 501 and stored image of die metrology mark 511 are shown in FIG. 5A. The substrate metrology mark 501 of FIG. 5A shows an image with 800×800 pixels (px), p₁=20 px. Die metrology mark 511 shows an image with p₂=21 px. It can be seen that the gratings of die metrology mark 511 has a slight rotation relative to the gratings of the substrate metrology mark 501. Hence, when the images are digitally superimposed to form an interference pattern, the light and dark region on the interference pattern 521 can be observed. Based on the equations, the resultant moiré interference pattern P_{F} of 420 px can be determined:

$${P}_{F} = \frac{( {p}_{1} {p}_{2} )}{( {p}_{1} - {p}_{2} )} = 420 px$$

FIG. 5B illustrates another example for determining metrology mark errors. The substrate metrology mark 502 of FIG. 5B shows an image with 800×800 pixels (px), p1=20 px. Die metrology mark 512 shows an image with p₂=25 px. It can also be seen that a slight rotation in the gratings of die metrology mark 512 relative to the gratings of the substrate metrology mark 502. Hence, the light and dark region on the interference pattern 522 can be observed. Using the equation above, the resultant moiré interference pattern P_{F} of 100 px can be determined. Accordingly, the metrology mark errors can be determined based on the image analysis of the moiré interference pattern.

Accordingly, the metrology mark error of die relative to the substrate can be obtained by observing the simulated overlay interference pattern. In this example, the substrate metrology mark and die metrology mark need not be directly placed above one another. Instead, moiré interference pattern is generated digitally by superimposing the substrate metrology mark and die metrology mark.

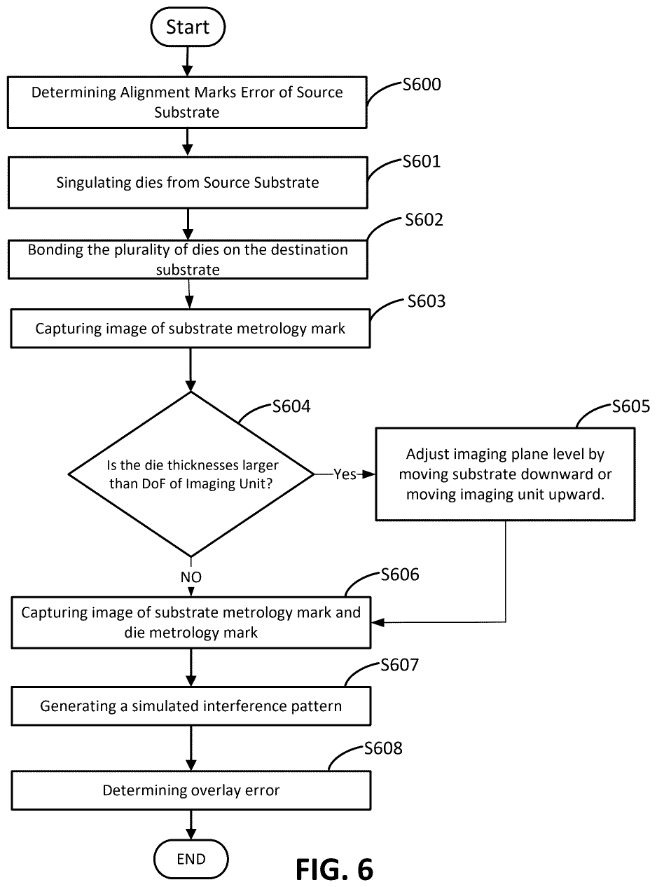

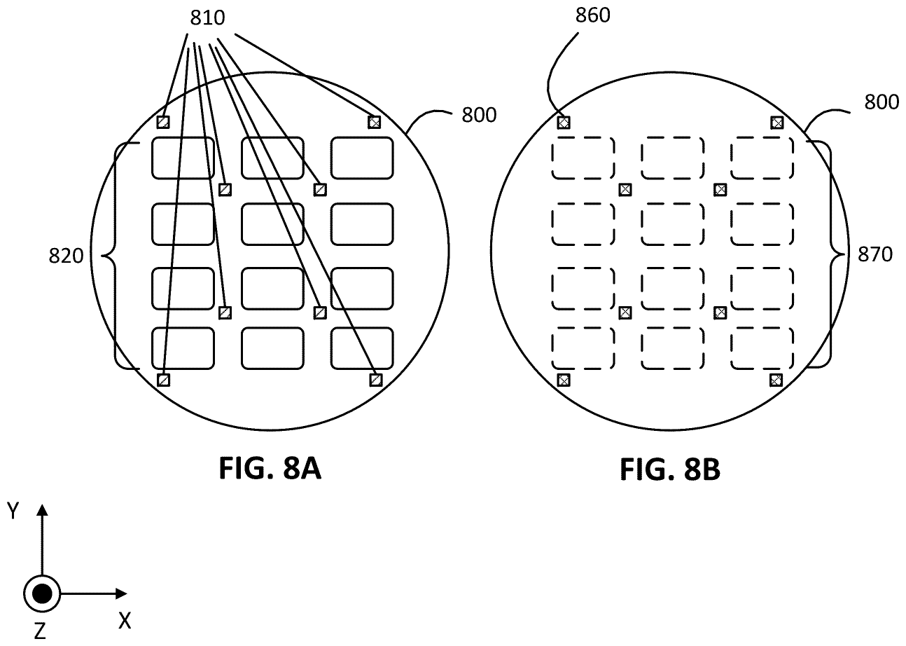

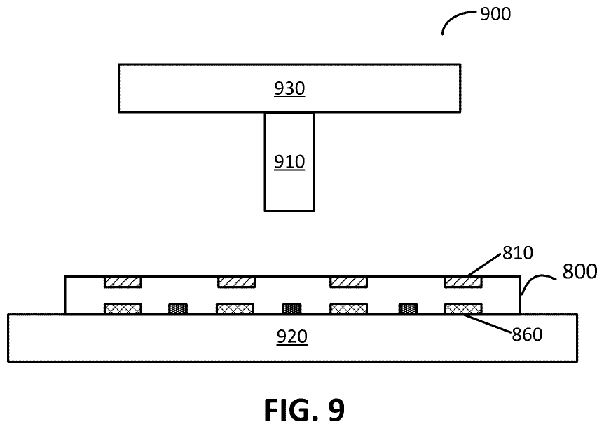

FIG. 6 is a flowchart illustrating an exemplary operation for determining a total overlay error of one of more die bonded on a substrate. For illustrative purposes, FIG. 6 will be explained with reference to the figures discussed above. The process begins in step S600 to determine alignment marks error of the source substrate 800. The determination of alignment marks error will be explained below with reference to FIGS. 8A, 8B, and FIG. 9. Referring to FIGS. 8A and 8B, an active side and the opposite non-active side of the source substrate 800 prior to a singulation process are shown, respectively, in accordance with an embodiment of the present disclosure. An array of dies 820 are fabricated on the active side of the source substrate 800. The non-active side of the source substrate 800 in FIG. 8B shows the backside of the array of dies 820, as dies 870. The dotted outline of the array of dies 870 indicates the ideal position of the alignment marks with respect to the dies on the active side. Each of the dies 870 includes one or more die metrology marks 111 in the non-active side as discussed above with respect to the singulated dies bonded on the product substrate 100 of FIG. 1.

As shown in FIG. 8A, a set of active side alignment marks 810 are fabricated on the unused area (non-die area) of the source substrate 800. While an array of 3×4 is shown in FIG. 8A, the array of dies can be arranged in other patterns. The active side alignment marks 810 can be dispersed in any pattern so long as the marks are fabricated in the unused portion of source substrate 800. In an alternative embodiment, some but not all of the active side alignment marks are fabricated in the unused portion of the source substrate 800. In some embodiments, alignment marks on the active side of source substrate 800 are prefabricated in the source substrate 800. These active side alignment marks 810 are representative of the alignment of the circuit/features on the active side.

Based on the positions of the set of active-side alignment marks 810, a set of corresponding non-active side alignment marks 860 are fabricated on the non-active side (backside) of the source substrate 800 as illustrated in FIG. 8B. These non-active side alignment marks 860 are placed on the non-active side which are collinear with the active side alignment marks 810.

Before the non-active side alignment marks 860 are made and the metrology information is obtained and stored in the memory of control unit 250, the non-singulated source substrate 800 can be thinned down, if necessary, to a desired thickness of for example less than 0.1 mm. The thinning techniques may be performed using one or more back grinding processes such as mechanical grinding, chemical mechanical planarization (CMP), wet etching, dry etching, plasma etching, or any other process of removing material in a controlled manner.

The active side of the source substrate 800 having a set of active side alignment marks 810 and the non-active side having a set of non-active side alignment marks 860. Thereafter, metrology can be performed by using an optical device such as a microscope, camera, or beam splitter that is capable of seeing through the source substrate 800. This may include an Infrared (IR) microscope or a vision system to look through IR transparent substrates.

FIG. 9 is an exemplary configuration for measuring alignment marks of the source substrate 800. In this example, a measurement system 900 may be set up outside of metrology apparatus 200. In another embodiment, the measurement system 900 is incorporated within the metrology apparatus 200. The measurement system 900 can be controlled by controller 250 of FIG. 2 or controlled by another controller in communication with controller 250. According to FIG. 9, source substrate 800 is placed on a substrate stage 920 with active side facing upward. The substrate stage 920 is capable of moving the source substrate 800 in the X, Y, Z and/or tilt directions. The active side of the source substrate 800 having a set of active side alignment marks 810 and the non-active side having a set of non-active side alignment marks 860. Thereafter, metrology can be performed by using an optical device 910 such as a microscope, camera, or beam splitter that is capable of seeing through the source substrate 800. This may include an Infrared (IR) microscope or a vision system to look through IR transparent substrates. The optical device can be coupled to a movable holding device 930. The optical device 910 performs metrology to obtain positional information of the active side alignment marks 810 and non-active side alignment marks 860 and compares them against each other to obtain the X-direction error information and the Y-direction error information or the X-direction error information, Y-direction error information, and rotation (θ) error information and provides the measurement result to the controller 250 or to a processor (not shown) connected to the controller 250 via a network. To enable observing both sets of marks 810 and 860, either the substrate stage 920 can move in Z-axis direction or the optical device 910 can use a Z-motion stage (not shown), which may be part of the holding device 930, to move the optical device in the Z-axis direction. Alternatively, the depth of field of the optical device 910 could be designed such that both sets of marks 810 and 860 are able to produce good contrast at a single relative location of the optical device to the substrate i.e. the depth of field of the optical device is large enough that both sets of marks 810 and 860 are in focus at a single location.

Based on the measurement result, the controller 250 determines the alignment marks placement errors in the X, Y, and θ (rotational) directions based on the offset between the measured positions of the active-side alignment marks 810 and non-active-side alignment marks 860 on the source substrate 800, where

$${Error}_{AlignmentMarks} ( i ) = \{ {e}_{{x}_{fronttoback}} ( i ) , {e}_{{y}_{fronttoback}} ( i ) , {e}_{{θ}_{fronttonack}} ( i ) \} \qquad ( 3 )$$

The Error_{AlignmentMarks} (i) is a measured placement error for each alignment mark (i) for a plurality of alignment marks 810 and 860 on the source substrate 800 at a specific position (x, y).

In one embodiment, the alignment marks may be thin marks that only allow measurement of the placement error in one or two of the dimensions {e_{xfronttoback}, e_{yfronttoback}, e_{θfronttoback}}. The full set of Error_{AlignmentMarks} may be fitted to a model f that describes the placement error (eₓ, e_{y}, e_{θ}) of the alignment marks across the source substrate 800 as a function of the mark location on the source substrate. The model f may also take into account the type of errors associated with the fabrication technique used to fabricate the marks. The model f may then be used to estimate the second alignment marks placement error on the non-active side of the dies. A simple model f, which may be useful when there is a high density of alignment marks, and the errors are small, is to take a local average of the nearest alignment marks. In another embodiment, a model which takes into account additional high spatial frequency errors such as magnification, skew, trapezoidal and high order polynomials could also be included as offsets and correction to die alignment control algorithm. In another embodiment, a linear least squares fitting may be performed to fit n-th degree polynomial of the model f in two dimensions to the error data.

In particular, the source substrate 800 has a set of active side alignment marks 810 (A). There are N active side alignment marks Aⱼ in the set of active side alignment marks 210 (A={A₁, . . . Aⱼ, . . . A_{N}}). Each active side alignment mark j is located at an active side alignment mark position Aⱼ on the active side of the source substrate 800. Active side alignment mark position Aⱼ includes a position {A_{j,x}, A_{j,y}} in the coordinate system of the substrate (Aᵢ={A_{j,x}, A_{j,y}}).

The non-active side of the source substrate is patterned with a set of corresponding non-active side alignment marks 810 (B) and set of die metrology marks 111 (C). There are N non-active side alignment marks Bⱼ in the set of non-active side alignment marks 810 (B={B₁, . . . Bⱼ, . . . B_{N}}). Each non-active side alignment mark j is located at non-active side alignment mark position Bⱼ on the non-active side of the source substrate 800. Ideally, the non-active side alignment mark positions Bⱼ should be collinearly located with active side alignment mark positions Aⱼ but on the back side of the substrate and they may have placement errors relative to active side alignment mark positions Aⱼ. The non-active side alignment mark position Bⱼ includes a position {B_{j,x}, B_{j,y}} in the coordinate system of the substrate (Bⱼ={B_{j,x}, B_{j,y}}).

Referring to FIG. 8B, there are M die metrology marks in the set of die metrology marks 111 (C={C₁, . . . Cᵢ, . . . C_{M}}). Each die metrology mark i is located at die metrology mark position Cᵢ on the non-active side of the source substrate 1030. The die metrology mark position Cᵢ includes a position {C_{i,x}, C_{i,y}} in the coordinate system of the substrate (Cᵢ={C_{i,x}, C_{i,y}}). There is at least one die metrology mark 111 for each die on the source substrate 800.

Returning to the flow, in step S601, the source substrate 800 is diced (singulated) into individual dies after the measurement. Each of the dies includes one or more metrology marks as illustrated in FIG. 1. The one or more metrology marks are on the outer side or backside (side that is opposite the side to be bonded to the destination substrate) of each of a plurality of dies. Any suitable metrology marks may be located at different locations of the substrate or the frame. The metrology marks may include a pattern such as grating lines as illustrated in FIG. 1. Each of the grating lines that form the metrology mark may be any suitable material, such as silicon, silicon oxide, metal, dielectric, and/or any other suitable material that reflects or absorbs light. The pitch between grating lines of the overlay metrology mark may be uniform or non-uniform.

Next, in step S602, the plurality of singulated dies are bonded to a destination substrate. The bonding method is not limited to a specific bonding method. For example, the bonding method may be bonding using an adhesive, bonding by hybrid bonding, atomic diffusion bonding, vacuum bonding, bump bonding or the combination of the like.

In step S603, an imaging unit such as imaging unit 210 of FIG. 2 captures one or more images of the substrate metrology mark and records the captured images in a global coordinate system as described above. In an alternative embodiment, step S603 is performed prior to steps S602. In another embodiment, step S603 is performed prior to the die being received by the metrology apparatus in step S601. After each of the substrate metrology marks have been captured and recorded, the flow proceeds to step S604.

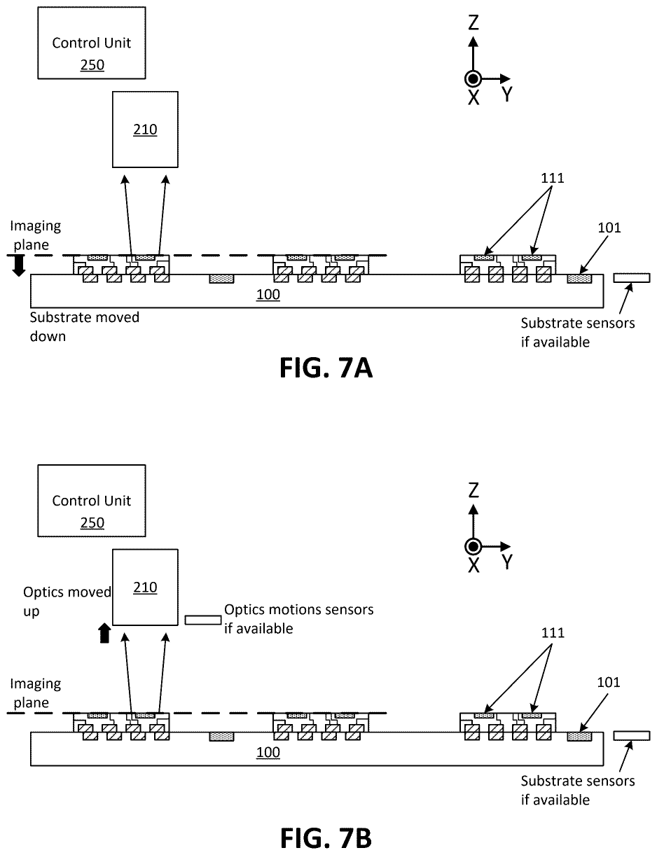

In step S604, thickness of the plurality of dies is obtained. The thickness of each of the plurality of dies may be obtained via measurement. The measurement may be performed with a gap sensor (not shown), for example, by an optical sensor (such as spectral interference sensors, interferometers, laser triangulation sensors, or other sensors such as air gauge, capacitive sensors, inductive sensors) provided on a bridge (not shown) on which imaging optics 210 are mounted, the substrate stage 220, or the base plate 230. If the thickness sensor is mounted on the substrate stage 220 or the base plate 230, then the measurement signal may be bounced off a mirror on the bridge. In another embodiment, the thickness may be obtained outside of the metrology apparatus 200 and recorded prior to the measurement process. In the event the die has a thickness larger than the Depth of Field (DoF) of the imaging unit 210 (Yes in step S604), the process proceeds to S605. If the die has a thickness larger than the DoF of the imaging unit 210, high quality images of the metrology marks cannot be obtained. Thus, the image plane should be adjusted to compensate for the DoF limitation of the imaging unit 210. FIGS. 7A and 7B illustrate solutions for compensating DoF limitation of the imaging unit 210. In FIG. 7A, the substrate is moved downward such that the image plane of the imaging unit 210 is also moved downward. This can be achieved by moving the base plate 230 downward by at least the thickness of the die. FIG. 7B illustrates another method for compensating DoF limitation of the imaging unit 210. In this illustrative embodiment, the imaging unit 210 is moved upward such that the imaging plane can be adjusted upward. By moving the imaging unit upward, the image of the die metrology mark 111 is adjusted to a DoF range that is suitable for the imaging unit 210 so that images of the metrology mark can be properly focused. In another embodiment, the imaging unit 210 can be adjusted by changing one or more optical components to change the position of the DoF range.

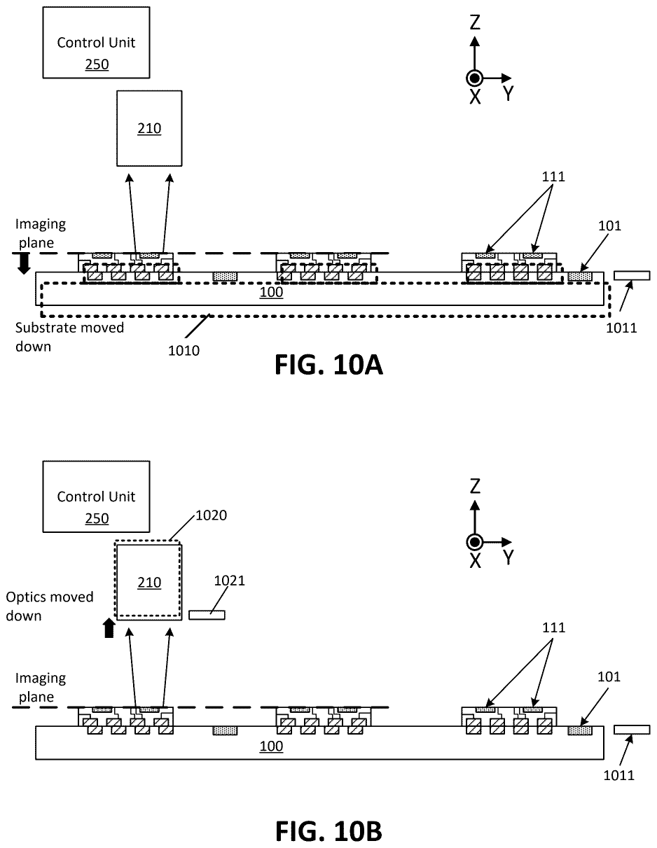

However, in the process of moving the substrate downward, such as illustrated in FIG. 7A, and moving the imaging unit upward, as illustrated in FIG. 7B, unintended movement or offset may result from such movements. FIGS. 10A and 10B illustrate the unintended parasitic errors, or offsets that occurred during the capturing of the first image and the second image, which may result in such moving parts. For example, the dotted object 1010 of FIG. 10A shows the actual position of the substrate after the destination substrate is moved downward, which represents an offset from the intended position (substrate with solid line) of the substrate. Similarly, the dotted object 1020 of FIG. 10B shows the actual position of the imaging unit 210 after the imaging unit 210 is moved upward, which represents an offset from the intended position of the imaging unit 210. The offset, or parasitic errors, (non-straightness, pitch, roll, yaw) εₓ(z), ε_{y}(z), ε_{θ}(z) associated with the substrate's motion or optics' motion can be measured, for example, with substrate sensor 1011 or optics sensor 1021, respectively, based on the following equation:

$${Offset}_{substrate or optics Z motion induced} ( z ) = [ {ε}_{x} ( z ) , {ε}_{y} ( z ) , {ε}_{θ} ( z ) ] = ( {Δ}_{measured} ( x , y , θ ) - {Δ}_{intended} ( x , y , θ ) ) , \qquad ( 4 )$$

where Δ_{measured}(x, y, θ) is the change in position measured by substrate sensor 1011 or optics sensor 1021, and Δ_{intended}(x, y, θ) is the change in intended position.

In the event the die does not have a thickness larger than the Depth of Field (DoF) of the imaging unit 210 (No in step S604) or step S605 is completed, the flow proceeds to step S606. In step S606, the control unit 250 causes imaging unit 210 to capture an image of the die metrology mark and record the captured image in a global coordinate system as described above. After each of the die metrology mark has been captured and recorded, the flow proceeds to step S607.

Now that both the substrate metrology marks 101 and die metrology marks 111 with positional and orientational information are captured and recorded in the same coordinate system, the control unit 210 generates a simulated moiré interference pattern by superposing the substrate metrology mark 101 and die metrology mark 111. Based on the simulated superposed interference pattern, metrology mark error in X, Y, and θ directions can be determined. In step S608, based on the simulated moiré interference pattern, an overlay error can be determined as described above. The total overlay error can be obtained by combining the Errror_{AlignmentMarks}(i), Offset_{substrate or optics Z motion induced}(z), and Error_{MetrologyMark} as follows:

$$Overlay error = {Error}_{AlignmentMarks} ( i ) + {Offset}_{substrate or optics Z motion induced} ( z ) + {Error}_{Metrology Mark} \qquad ( 6 )$$

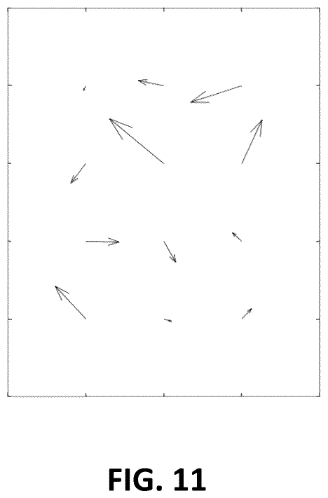

The overlay error may be compared with a threshold, if the overlay error is below an acceptable threshold value, the product substrate is deemed acceptable. For example, the threshold value may be in the range of 50 nm to 2 μm. The control unit 250 can be configured to correct the positional deviation between the plurality of dies and the substrate, based on the repeatable portion of the determined overlay errors. The process shall be repeated for each of the substrate metrology mark 101 and die metrology mark 111. In one embodiment, the measurement results, such as the overlay error, from multiple metrology marks can be presented as a quiver plot as illustrated in FIG. 11 where each of the arrows represent the magnitude and direction of the measured overlay error of a die bonded to the destination substrate. In one embodiment, the measurement result is sent to a database on a network. An operator will then use the measurement results to perform one or more of the following tasks: grade the quality of the result of the bonded device; rework the bonded device; adjust the manufacturing process of the die; and adjust the manufacturing process of the substrate; and adjust the bonding process of the die to the substrate.

### <Embodiment of Article Manufacturing Method>

A method of manufacturing an article (a semiconductor IC element, a liquid crystal element, a MEMS, or the like) using the above-described apparatus will be described. The article manufacturing method according to the embodiment of the present disclosure is suitable for, for example, manufacturing an article such as a microdevice (for example, a semiconductor device) or an element having a microstructure. The article manufacturing method according to the embodiment includes a step of bonding a die to a destination substrate using the above-described bonding apparatus, a step of processing the destination substrate to which the is the dies are bonded, and a step of manufacturing an article from the processed first member. The subsequent step is another known step including probing, dicing, annealing, bonding, packaging, and the like. The article manufacturing method according to the embodiment is superior to a conventional method in at least one of the performance, quality, productivity, and production cost of an article.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like. While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

What is claimed is:

1. A method of measuring an overlay error of at least one die bonded to a substrate, the method comprising:
capturing a first image, by an imaging device, of at least one first metrology mark having a first pattern on an object with a first positional information;
capturing a second image, by the imaging device, of at least one second metrology mark having a second pattern on a surface of the at least one die with a second positional information;
superposing the second image with the first image to form a simulated interference pattern;
determining a metrology mark error based on the simulated interference pattern in X, Y and θ directions; and
obtaining the overlay error based on alignment marks placement errors of a source substrate, offsets that occurred during the capturing of the first image and the second image, and the determined metrology mark error.

2. The method of claim 1, further comprising:
recording the first image to a global coordinate system based on the first positional information and storing the first image in a memory; and
recording the second image to the global coordinate system based on the second positional information and storing the second image in the memory.

3. The method of claim 1, wherein the object is the substrate.

4. The method of claim 1, wherein the object is a frame that has a fixed positional relationship with the substrate when the substrate is releasably secured by a chuck.

5. The method of claim 1, wherein the first pattern and the second pattern comprise of a plurality of uniformly or non-uniformly spaced gratings.

6. The method of claim 1, wherein the overlay error is compared with an acceptable threshold value.

7. The method of claim 1, wherein the determined overlay error includes error in X, Y and θ directions.

8. The method of claim 1, wherein the first pattern and the second pattern are complementary patterns that includes one or more of: box in box, bar in bar, cross-in-cross, checkerboard, bullseye, moiré patterns, vernier scale marks, or cross-in-box pattern.

9. The method of claim 1, wherein the alignment marks placement error is determine based on offsets between positions of at least one active-side alignment marks on an active side of the source substrate and positions of at least one first non-active side alignment marks on a non-active side of the source substrate in the X, Y, and θ directions.

10. The method of claim 1, wherein the offset occurred during the capturing of the first image and the second image, when the imaging device and the substrate are moved relative to each other in a Z direction to accommodate for the depth of field (DoF) limitation of the imaging device, and
wherein the offset occurred during the capturing of the first image and the second image are obtained by at least one of:
measuring positions of the substrate relative to intended positions of the substrate; and
measuring positions of the imaging device relative to an intended position of the imaging device.

11. A system of measuring an overlay error of at least one die bonded to a substrate, the system comprising:
an imaging device configured to capture a first image of at least one first metrology mark having a first pattern on the substrate with a first positional information, and capturing a second image, by the imaging device, of at least one second metrology mark having a second pattern on a surface of the at least one die with a second positional information;
at least one memory storing a stored instructions; and
at least one processor that executes the stored instructions, which cause the at least one processor to:
superpose the second image with the first image to form a simulated interference pattern; and
determine a metrology mark error based on the simulated interference pattern; and
obtain the overlay error based on alignment marks placement errors of a source substrate, offsets occurred during the capturing of the first image and the second image, and the determined metrology mark error.

12. The system of claim 11, wherein the stored instructions further cause the at least one processor to:
record the first image to a global coordinate system based on the first positional information and storing the first image in the at least one memory; and
record the second image to the global coordinate system based on the second positional information and storing the second image in the at least one memory.

13. The system of claim 11, wherein the at least one first metrology mark is on the substrate.

14. The system of claim 11, wherein the at least one first metrology mark is on a frame with a fixed positional relationship with the substrate held by a substrate chuck.

15. The system of claim 11, wherein the first pattern and the second pattern comprise of a plurality of uniformly or non-uniformly spaced gratings.

16. The system of claim 11, wherein the overlay error is compared with an acceptable threshold value.

17. The system of claim 11, wherein the determined overlay error includes errors in the X, Y and θ directions.

18. The system of claim 11, wherein the first pattern and the second pattern are complementary pattern that includes box in box, bar in bar, cross-in-cross, checkerboard, bullseye, moiré patterns, vernier scale marks, or cross-in-box pattern.

19. The system of claim 11, wherein the alignment marks placement error is determine based on offsets between positions of at least one active-side alignment marks on an active side of the source substrate and positions of at least one first non-active side alignment marks on a non-active side of the source substrate in the X, Y, and θ directions.

20. The system of claim 11, wherein the offset occurred during the capturing of the first image and the second image when the imaging device or the substrate is moved in a Z direction to accommodate for the depth of field (DoF) limitation of the imaging device, and
wherein the offsets occurred during the capturing of the first image and the second image are obtained by:
a first sensor configured to measure positions of the substrate relative to intended positions of the substrate; or
a second sensor configured to measure positions of the imaging device relative to an intended positions of the imaging device.
